(19) United States
(12) Patent Application Publication
(10) Pub. No.: US 2022/0093816 A1
(43) Pub. Date: Mar. 24, 2022

(54) METHOD FOR MANUFACTURING ELEMENT MOUNTING SUBSTRATE

(71) Applicant: NITTO DENKO CORPORATION, Ibaraki-shi, Osaka (JP)

(72) Inventors: Toru ISEKI, Ibaraki-shi (JP); Makoto SAITO, Ibaraki-shi (JP); Mitsuhiro KANADA, Ibaraki-shi (JP)

(73) Assignee: NITTO DENKO CORPORATION, Ibaraki-shi, Osaka (JP)

(21) Appl. No.: 17/421,798

(22) PCT Filed: Dec. 3, 2019
(86) PCT No.: PCT/JP2019/047142

§ 371 Date: Jul. 9, 2021

(30) Foreign Application Priority Data
Feb. 26, 2019 (JP) 2019-033021

(51) Int. Cl. H01L 33/00; H01L 25/075; H01L 21/683; H01L 33/48

(52) U.S. Cl. CPC H01L 33/005; H01L 25/0753; H01L 2933/0033; H01L 33/48; H01L 21/6835

(57) ABSTRACT

Provided is a method of manufacturing an element-mounted substrate having mounted thereon elements with high positional accuracy. The method of manufacturing an element-mounted substrate of the present invention is a method of manufacturing an element-mounted substrate having elements mounted on a substrate, the method including: a step (I) of preparing a temporary fixing material with elements having arrayed thereon the elements by holding one surface of each of the elements on a temporary fixing material; a step (II) of arranging the temporary fixing material with elements on the substrate so that another surface of each of the elements adheres onto the substrate; and a step (III) of peeling the temporary fixing material from the elements adhering onto the substrate.

### TECHNICAL FIELD

The present invention relates to a method of manufacturing an element-mounted substrate.

### BACKGROUND ART

In recent years, an investigation has been made on the miniaturization of various elements such as a LED for the purposes of, for example, a cost reduction and the expression of new performance.

In general, the LED has a size of from about 500 μm□ (μm per square: hereinafter referred to as μm/square) to about 1,000 μm/square and a thickness of from about 100 μm to about 200 μm. Accordingly, when the LED is mounted under so-called 3σ control, positional accuracy required at the time of the performance of the mounting is said to be around ±10 μm.

When the various elements such as the LED are miniaturized, it becomes extremely difficult to mount the elements with high positional accuracy. For example, a micro LED that is considerably miniaturized as compared to a related-art LED generally has a minute size, specifically, a plane size of from about 3 μm/square to about 30 μm/square and a thickness of from about 1 μm to about 10 μm. When an attempt is made to mount such element with high positional accuracy, required positional accuracy is around plus minus several tens of nanometers. A related-art method of manufacturing an element-mounted substrate cannot achieve mounting with such high positional accuracy.

For example, a manufacturing method including utilizing transfer onto a substrate by laser light irradiation has been reported as the related-art method of manufacturing an element-mounted substrate (Patent Literature 1). In such manufacturing method, however, a positional shift at the time of mounting occurs owing to an influence of air resistance at the time of the transfer, and hence it is difficult to perform the mounting with high positional accuracy.

### CITATION LIST

### Patent Literature

[PTL 1] JP 2010-161221 A

### SUMMARY OF INVENTION

### Technical Problem

An object of the present invention is to provide a method of manufacturing an element-mounted substrate having mounted thereon an element with high positional accuracy.

### Solution to Problem

According to one embodiment of the present invention, there is provided a method of manufacturing an element-mounted substrate having elements mounted on a substrate, the method including:

a step (I) of preparing a temporary fixing material with elements having arrayed thereon the elements by holding one surface of each of the elements on a temporary fixing material;

a step (II) of arranging the temporary fixing material with elements on the substrate so that another surface of each of the elements adheres onto the substrate; and

a step (III) of peeling the temporary fixing material from the elements adhering onto the substrate.

In one embodiment, each of the elements is a LED chip.

In one embodiment, the LED chip is a micro LED chip.

### Advantageous Effects of Invention

According to the present invention, there can be provided the method of manufacturing an element-mounted substrate having mounted thereon elements with high positional accuracy.

### BRIEF DESCRIPTION OF DRAWINGS

FIG. 1 is a schematic sectional view of a temporary fixing material with elements to be obtained in a step (I) of preparing a temporary fixing material with elements.

FIG. 2 is an explanatory view of a step (II) of arranging the temporary fixing material with elements.

FIG. 3 is an explanatory view of a step (III) of peeling the temporary fixing material.

FIG. 4 are explanatory views for illustrating a method of manufacturing an element-mounted substrate according to a second embodiment of the present invention.

### DESCRIPTION OF EMBODIMENTS

### Method of Manufacturing Element-Mounted Substrate According to Embodiment of the Present Invention

A method of manufacturing an element-mounted substrate of the present invention is a method of manufacturing an element-mounted substrate having elements mounted on a substrate. According to the method of manufacturing an element-mounted substrate of the present invention, the elements can be mounted with high positional accuracy, and hence a reduction in yield due to a mounting position failure can be eliminated.

The method of manufacturing an element-mounted substrate of the present invention includes a step (I) of preparing a temporary fixing material with elements, a step (II) of arranging the temporary fixing material with elements, and a step (III) of peeling the temporary fixing material. The method of manufacturing an element-mounted substrate of the present invention may include the plurality of steps (I) of preparing a temporary fixing material with elements. The method of manufacturing an element-mounted substrate of the present invention may include the plurality of steps (II) of arranging the temporary fixing material with elements. The method of manufacturing an element-mounted substrate of the present invention may include the plurality of steps (III) of peeling the temporary fixing material. The method of manufacturing an element-mounted substrate of the present invention may include any appropriate other step to the extent that the effect of the present invention is not impaired as long as the method includes the step (I) of preparing a temporary fixing material with elements, the step (II) of arranging the temporary fixing material with elements, and the step (III) of peeling the temporary fixing material. For example, the method may include a step of forming a wiring with a semiconductor photolithography apparatus, such as a stepper, after the mounting of the elements.

### Step (I) of Preparing Temporary Fixing Material with Elements

In the step (I) of preparing a temporary fixing material with elements, a temporary fixing material with elements having arrayed thereon the elements is prepared by holding one surface of each of the elements on a temporary fixing material.

In the description of the present invention, the term “one surface of each of the elements” means one surface out of the two surfaces of each of the elements substantially opposite to each other, and the term “another surface of each of the elements” means a surface opposite to the “one surface of each of the elements” out of the two surfaces of each of the elements substantially opposite to each other.

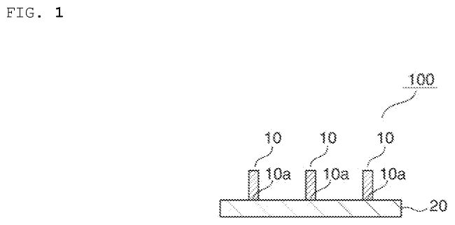

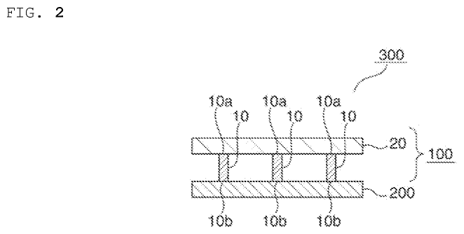

A schematic sectional view of a temporary fixing material with elements to be obtained in the step (I) of preparing a temporary fixing material with elements is illustrated in FIG. 1. In FIG. 1, a temporary fixing material 100 with elements has arrayed thereon elements 10 through the holding of one surface 10a of each of the elements 10 on a temporary fixing material 20.

The temporary fixing material with element only needs to be prepared by any appropriate method to the extent that the effect of the present invention is not impaired as long as the method includes holding one surface of each of the elements on the temporary fixing material to array the elements. An example of such method is a method including: arranging a film-like adhesive, such as a die attach film, on one surface of each of the elements; and temporarily fixing the another surface of each of the elements onto the temporary fixing material, such as an adsorption sheet, a slightly pressure-sensitive adhesive tape, a UV-peelable pressure-sensitive adhesive tape, or a heat-peelable pressure-sensitive adhesive tape, to array the elements.

### Step (II) of Arranging Temporary Fixing Material with Elements

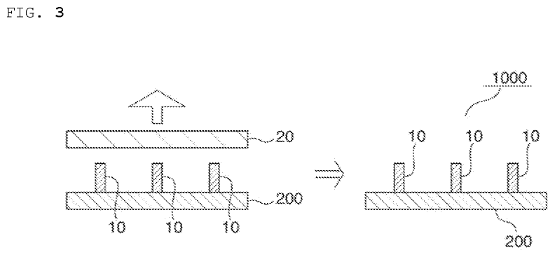

In the step (II) of arranging the temporary fixing material with elements, the temporary fixing material with elements is arranged on the substrate so that the another surface of each of the elements held on the temporary fixing material with elements adheres onto the substrate. An explanatory view of the step (II) of arranging the temporary fixing material with elements is illustrated in FIG. 2. In FIG. 2, a element-mounted substrate 300 with a temporary fixing material is obtained by arranging the temporary fixing material 100 with elements so that the other surface 10b of each of the elements 10 adheres onto a substrate 200.

The mounted substrate with a temporary fixing material only needs to be produced by any appropriate method to the extent that the effect of the present invention is not impaired as long as the method includes arranging the temporary fixing material with elements on the substrate so that the another surface of each of the elements held on the temporary fixing material with elements adheres onto the substrate. An example of such method is a method including bonding the surface of each of the elements arrayed on the temporary fixing material, the surface having arranged thereon a film-like adhesive, such as a die attach film, to the substrate such as a silicon substrate while adjusting its position. Examples of such bonding method include bonding through pressure bonding, bonding under reduced pressure, bonding under pressure, and bonding under heating.

### Step (III) of Peeling Temporary Fixing Material

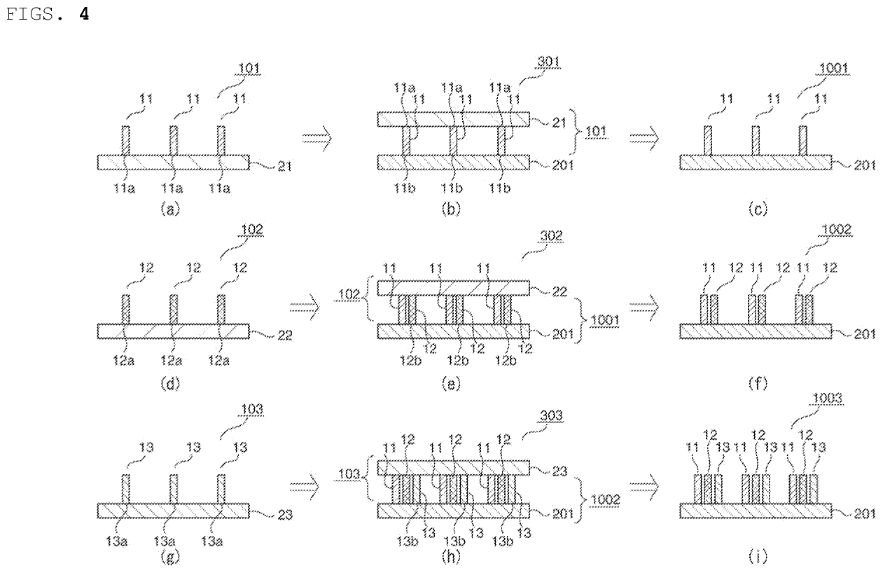

In the step (III) of peeling the temporary fixing material, the temporary fixing material is peeled from the element adhering onto the substrate. An explanatory view of the step (III) of peeling the temporary fixing material is illustrated in FIG. 3. In FIG. 3, the temporary fixing material 20 is peeled from the element-mounted substrate 300 with a temporary fixing material obtained by the step (II) of arranging the temporary fixing material with elements. Thus, an element-mounted substrate 1000 having the elements 10 mounted on the substrate 200 is obtained.

The element-mounted substrate only needs to be produced by any appropriate method to the extent that the effect of the present invention is not impaired as long as the method includes peeling the temporary fixing material from the elements adhering onto the substrate. For example, the following methods are each available as such method: when the temporary fixing material is an adsorption sheet or a slightly pressure-sensitive adhesive tape, a method such as peeling is available; when the temporary fixing material is a UV-peelable pressure-sensitive adhesive tape, a method such as peeling through UV irradiation is available; and when the temporary fixing material is a heat-peelable pressure-sensitive adhesive tape, a method such as peeling under heating is available.

### First Embodiment

A method of manufacturing an element-mounted substrate according to one embodiment (first embodiment) of the present invention is a method in which one kind of elements are used, and an element-mounted substrate having the one kind of elements mounted on a substrate is manufactured by including each of the step (I) of preparing a temporary fixing material with elements, the step (II) of arranging the temporary fixing material with elements, and the step (III) of peeling the temporary fixing material once. The element-mounted substrate is typically the element-mounted substrate 1000 having the elements 10 mounted on the substrate 200 as illustrated in FIG. 3. In this case, the elements 10 are mounted on the substrate 200 with high positional accuracy.

### Second Embodiment

A method of manufacturing an element-mounted substrate according to another embodiment (second embodiment) of the present invention is a method in which “n” kinds (where “n” represents an integer of 2 or more) of elements are used, and an element-mounted substrate having the “n” kinds of elements mounted on a substrate is manufactured by including each of the step (I) of preparing a temporary fixing material with elements, the step (II) of arranging the temporary fixing material with elements, and the step (III) of peeling the temporary fixing material “n” times.

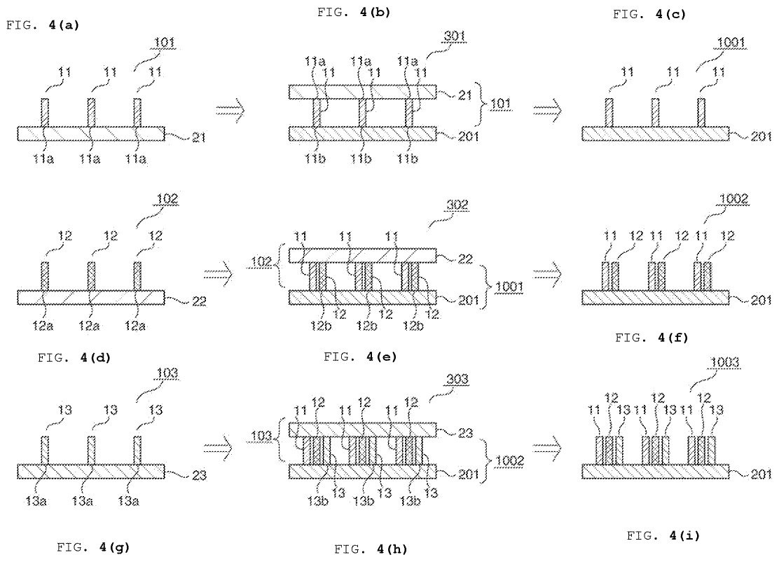

The second embodiment is specifically described with reference to FIG. 4. FIG. 4 are each an illustration of a case in which three kinds of elements are used.

FIG. 4(a) is a schematic sectional view of a temporary fixing material with elements to be obtained in the step (I) of preparing a temporary fixing material with elements by using first elements 11. In FIG. 4(a), a temporary fixing material 101 with elements has arrayed thereon the first elements 11 through the holding of one surface 11a of each of the elements 11 on a temporary fixing material 21.

FIG. 4(b) is a schematic sectional view of a mounted substrate with a temporary fixing material to be obtained in the step (II) of arranging the temporary fixing material with elements. In FIG. 4(b), a mounted substrate 301 with a temporary fixing material is obtained by arranging the temporary fixing material 101 with elements under a vertically inverted state so that the other surface 11b of each of the elements 11 adheres onto a substrate 201.

FIG. 4(c) is a schematic sectional view of an element-mounted substrate to be obtained in the step (III) of peeling the temporary fixing material. In FIG. 4(c), an element-mounted substrate 1001 is such that the elements 11 are mounted on the substrate 201 by peeling the temporary fixing material 21 from the element-mounted substrate 301 with a temporary fixing material.

FIG. 4(d) is a schematic sectional view of a temporary fixing material with elements to be obtained in the step (I) of preparing a temporary fixing material with elements by using second elements 12. In FIG. 4(d), a temporary fixing material 102 with elements has arrayed thereon the second elements 12 through the holding of one surface 12a of each of the elements 12 on a temporary fixing material 22.

FIG. 4(e) is a schematic sectional view of a mounted substrate with a temporary fixing material to be obtained in the step (II) of arranging the temporary fixing material with elements. In FIG. 4(e), a mounted substrate 302 with a temporary fixing material is obtained by arranging the temporary fixing material 102 with elements under a vertically inverted state so that the other surface 12b of each of the elements 12 adheres onto the element-mounted substrate 1001 obtained in advance. At the time of the production of the mounted substrate 302 with a temporary fixing material, for example, when the array pattern of the first elements 11 and the array pattern of the second elements 12 are identical to each other, the respective first elements 11 and second elements 12 can be arranged in the same array pattern by arranging the temporary fixing material with elements so that the positions of the second elements 12 shift from the positions of the first elements 11 as illustrated in FIG. 4(e).

FIG. 4(f) is a schematic sectional view of an element- mounted substrate to be obtained in the step (III) of peeling the temporary fixing material. In FIG. 4(f), an element-mounted substrate 1002 is such that the elements 11 and the elements 12 are mounted on the substrate 201 by peeling the temporary fixing material 22 from the element-mounted substrate 302 with a temporary fixing material. When the array pattern of the first elements 11 and the array pattern of the second elements 12 are identical to each other, as described above, the respective first elements 11 and second elements 12 can be arranged in the same array pattern by arranging the temporary fixing material with elements in the preceding step so that the positions of the second elements 12 shift from the positions of the first elements 11.

FIG. 4(g) is a schematic sectional view of a temporary fixing material with elements to be obtained in the step (I) of preparing a temporary fixing material with elements by using third elements 13. In FIG. 4(g), a temporary fixing material 103 with elements has arrayed thereon the third elements 13 through the holding of one surface 13a of each of the elements 13 on a temporary fixing material 23.

FIG. 4(h) is a schematic sectional view of a mounted substrate with a temporary fixing material to be obtained in the step (II) of arranging the temporary fixing material with elements. In FIG. 4(h), a mounted substrate 303 with a temporary fixing material is obtained by arranging the temporary fixing material 103 with elements under a vertically inverted state so that the other surface 13b of each of the elements 13 adheres onto the element-mounted substrate 1002 obtained in advance. At the time of the production of the mounted substrate 303 with a temporary fixing material, for example, when the array pattern of the first elements 11, the array pattern of the second elements 12, and the array pattern of the third elements 13 are identical to each other, the respective first elements 11, second elements 12, and third elements 13 can be arranged in the same array pattern by arranging the temporary fixing material with elements so that the positions of the third elements 13 shift from the positions of the first elements 11 and the second elements 12 as illustrated in FIG. 4(h).

FIG. 4(i) is a schematic sectional view of an element-mounted substrate to be obtained in the step (III) of peeling the temporary fixing material. In FIG. 4(i), an element-mounted substrate 1003 is such that the elements 11, the elements 12, and the elements 13 are mounted on the substrate 201 by peeling the temporary fixing material 23 from the element-mounted substrate 303 with a temporary fixing material. When the array pattern of the first elements 11, the array pattern of the second elements 12, and the array pattern of the third elements 13 are identical to each other, as described above, the respective first elements 11, second elements 12, and third elements 13 can be arranged in the same array pattern by arranging the temporary fixing material with elements in the preceding step so that the positions of the third elements 13 shift from the positions of the first elements 11 and the second elements 12.

In the second embodiment, for example, when three kinds of elements are used as illustrated in FIG. 4, any appropriate elements may be adopted as the three kinds of elements to the extent that the effect of the present invention is not impaired. For example, the R element, G element, and B element of a micro LED may be adopted as such elements. When the second embodiment is performed by using the R element, G element, and B element of the micro LED according to the method of manufacturing an element-mounted substrate of the present invention, the R element, G element, and B element of the micro LED can be arranged with high positional accuracy and in a regular pattern array as illustrated in FIG. 4(i).

### Element

Any appropriate element may be adopted as the element that may be adopted in the present invention to the extent that the effect of the present invention is not impaired. Such element is typically a semiconductor element, and examples thereof include a LED, a micro LED, or a mini LED.

Any appropriate size may be adopted as the size of each of the elements that may be adopted in the present invention to the extent that the effect of the present invention is not impaired. In the present invention, even when a miniaturized element is adopted, the element can be mounted with high positional accuracy. Accordingly, there can be adopted not only of course an element having a size at the level of that of a LED, specifically, from about 500 μm□ (pm per square: hereinafter referred to as μm/square) to about 1,000 μm/square, and an element having a size at the level of that of a mini LED, specifically, a thickness of from about 100 μm to about 200 μm but also an element having a size at the level of that of a micro LED, specifically, a plane size of from about 3 μm/square to about 30 μm/square and a thickness of from about 1 μm to about 10 μm. In addition, the method of manufacturing an element-mounted substrate of the present invention is applicable to an element having a nano-level size (e.g., from 1 nm to 1,000 nm) that is even smaller than the element having a size at the level of that of the micro LED.

The number of kinds of the elements may be only one, or may be two or more. When portions having different colors are present in one element (e.g., the R element, G element, and B element of a micro LED), the element is treated as a plurality of kinds of elements.

### Temporary Fixing Material

Any appropriate temporary fixing material may be adopted as the temporary fixing material that may be adopted in the present invention to the extent that the effect of the present invention is not impaired. It is preferred that such temporary fixing material can temporarily hold thereon one surface of the element in the step (I) of preparing a temporary fixing material with elements, enable the arrangement and adhesion of the another surface of each of the elements on the substrate in the step (II) of arranging the temporary fixing material with elements under the state of temporarily holding thereon the elements, and can be peeled from the elements in the step (III) of peeling the temporary fixing material.

Examples of such temporary fixing material include an adsorption sheet, a slightly pressure-sensitive adhesive tape, a UV-peelable pressure-sensitive adhesive tape, and a heat-peelable pressure-sensitive adhesive tape.

Examples of the adsorption sheet include a silicone sheet, a silicone foam sheet, a polyurethane sheet, a polyurethane foam sheet, a polyester sheet, and a polyester foam sheet each having adsorptivity.

Examples of the slightly pressure-sensitive adhesive tape include an SPV series, an E-MASK series, and an ELEP MASKING series manufactured by Nitto Denko Corporation.

Examples of the UV-peelable pressure-sensitive adhesive tape include an ELEP HOLDER series and an ELEP MOUNT series manufactured by Nitto Denko Corporation.

Examples of the heat-peelable pressure-sensitive adhesive tape include a REVALPHA series manufactured by Nitto Denko Corporation.

Any appropriate thickness may be adopted as the thickness of the temporary fixing material to the extent that the effect of the present invention is not impaired. Such thickness is preferably from 1 μm to 800 μm because the effect of the present invention can be further expressed, and the thickness is more preferably from 2 μm to 500 μm, still more preferably from 5 μm to 200 μm, particularly preferably from 10 μm to 150 μm.

The temporary fixing material may include any appropriate other layer on its side opposite to the surface on which the element is temporarily fixed to the extent that the effect of the present invention is not impaired.

### Substrate

Any appropriate substrate may be adopted as the substrate that may be adopted in the present invention to the extent that the effect of the present invention is not impaired. Examples of such substrate include: a silicon substrate; a polycrystalline silicon substrate; a sapphire substrate; a silicon carbide substrate; a compound semiconductor (gallium phosphide, gallium arsenide, indium phosphide, or gallium nitride) substrate; a glass epoxy substrate; an organic material substrate, such as polyimide; a glass substrate; a ceramic substrate; and a metal substrate.

Any appropriate thickness may be adopted as the thickness of the substrate to the extent that the effect of the present invention is not impaired. Such thickness is preferably from 10 μm to 10,000 μm because the effect of the present invention can be further expressed, and the thickness is more preferably from 15 μm to 1,000 μm, still more preferably from 20 μm to 500 μm, particularly preferably from 30 μm to 300 μm.

The substrate may include any appropriate other layer on its side opposite to the surface on which the element is mounted to the extent that the effect of the present invention is not impaired.

### EXAMPLES

The present invention is specifically described below by way of Example. However, the present invention is by no means limited to the Example. Test and evaluation methods in Example and the like are as described below. The term “part(s)” means “part(s) by mass” unless otherwise stated, and the term “%” means “mass %” unless otherwise stated.

### Method of evaluating Positional Accuracy of Mounting

The positional accuracy of arrayed R, G, and B elements was evaluated. A case in which a distance between the adjacent two of the R, G, and B elements was 50 μm or less was evaluated as ○, and a case in which the distance was more than 50 μm was evaluated as ×.

### Example 1

A die attach film was arranged on one surface of the G element of a 20-micrometer size micro LED, and a 100-micrometer thick silicone foam sheet having adsorptivity was bonded to the other surface thereof. Next, the surface of the die attach film was bonded to a 150-micrometer thick silicon substrate while its position was adjusted, followed by pressure bonding. After that, the silicone foam sheet was peeled.

Next, a die attach film was arranged on one surface of the R element of the 20-micrometer size micro LED, and a 100-micrometer thick silicone foam sheet having adsorptivity was bonded to the other surface thereof. The surface of the die attach film was bonded to the silicon substrate so that a Bayer array was obtained, followed by pressure bonding. After that, the silicone foam sheet was peeled.

Further, a die attach film was arranged on one surface of the B element of the 20-micrometer size micro LED, and a 100-micrometer thick silicone foam sheet having adsorptivity was bonded to the other surface thereof. The surface of the die attach film was bonded to the silicon substrate so that a Bayer array was obtained, followed by pressure bonding. After that, the silicone foam sheet was peeled.

Thus, an element-mounted substrate (1) in which the R, G, and B elements of the micro LED were arrayed on the silicon substrate was obtained.

The result of the evaluation of the positional accuracy of the mounting was ○.

### Comparative Example 1

The same procedure as that of Example 1 was followed except that DUNPLON TAPE No. 375 (manufactured by Nitto Denko Corporation, OPP tape for packaging) having a large pressure-sensitive adhesive strength was used as a temporary fixing material. As a result, the R, G, and B elements of the micro LED could not be arrayed on the silicon substrate.

### INDUSTRIAL APPLICABILITY

According to the method of manufacturing an element-mounted substrate of the present invention, there can be provided the element-mounted substrate having mounted thereon elements with high positional accuracy. Accordingly, the method can be effectively utilized in the manufacture of the element-mounted substrate having mounted thereon the miniaturized elements, such as a micro LED.

1. A method of manufacturing an element-mounted substrate having elements mounted on a substrate, the method comprising:
a step (I) of preparing a temporary fixing material with elements having arrayed thereon the elements by holding one surface of each of the elements on a temporary fixing material;
a step (II) of arranging the temporary fixing material with elements on the substrate so that another surface of each of the elements adheres onto the substrate; and
a step (III) of peeling the temporary fixing material from the elements adhering onto the substrate.

2. The method of manufacturing an element-mounted substrate according to claim 1, wherein the each of the elements is a LED chip.

3. The method of manufacturing an element-mounted substrate according to claim 2, wherein the LED chip is a micro LED chip.
